(19) United States
(12) Patent Application Publication
(10) Pub. No.: US 2010/0302520 A1
(43) Pub. Date: Dec. 2, 2010

(54) CLUSTER E-BEAM LITHOGRAPHY SYSTEM

(75) Inventor: Archie Hwang, Hsinchu County (TW)

Correspondence Address: Sawyer Law Group, P.C., P.O. Box 51418, Palo Alto, CA, 94303, US

(73) Assignee: Hermes-Microvision, Inc., Hsinchu (TW)

(21) Appl. No.: 12/855,538

(22) Filed: Aug. 12, 2010

Related U.S. Application Data
(63) Continuation-in-part of application No. 12/259,280, filed on Oct. 27, 2008.
(60) Provisional application No. 61/044,633, filed on Apr. 14, 2008.
(60) Provisional application No. 60/983,130, filed on Oct. 26, 2007.

(51) Int. Cl. G03B 27/42; H01J 37/141; H01J 37/12; H01J 37/30

(52) U.S. Cl. 355/53; 250/396 ML; 250/396 R; 355/77

(57) ABSTRACT

A hybrid lithography system is disclosed to achieve high throughput and high resolution of sub 32 nm lithography. The hybrid system contains an optical lithographer for expose pattern area where features above 32 nm, and a cluster E-beam lithography system for expose pattern area where features is sub 32 nm

### CROSS REFERENCE TO RELATED APPLICATIONS

This application is a continuation-in-part of U.S. application Ser. No. 12/259,280 filed Oct. 27, 2008 and entitled “Cluster E-Beam Lithography System”, which claims priority to provisional patent application 61/044,633, filed on Apr. 14, 2008, entitled “Cluster E-Beam Lithography System” and provisional patent application 60/983,130, filed on Oct. 26, 2007, entitled “Cluster E-Beam Lithography System”.

### BACKGROUND OF THE INVENTION

1. Field of the Invention

The present invention relates to an advanced lithography system to gain high throughput and high resolution in semiconductor lithography practice, and more particularly, to a hybrid system that combines optical and E-beam lithography (EBL) system to achieve the object.

2. Description of the Prior Art

Fabrication of semiconductor device such as logic and memory device may include processing wafer through various semiconductor processing tools. As feature size continuous shrink from 45 nm to 32 nm, conventional high throughput optical lithography system does not have high enough resolution for sub 32 nm nodes. The conventional E-beam lithography system has high resolution but has very low throughput during lithography practice.

Therefore, an improved system to achieve both high resolution and high throughput is desired.

### SUMMARY OF THE INVENTION

The present invention relates to an advanced lithography system to gain high throughput and high resolution in semiconductor lithography practice. More specifically, embodiments of the present invention provide a hybrid system that combines optical and E-beam lithography system to achieve the object. Merely by way of example, the present invention has been used onto smallest feature lithograph such as gate, AA (active area) and contact, but it would be recognized that the invention has a much broader range of applicability.

The present invention provides a hybrid lithography system, which comprises an optical lithographer for exposing rough patterns on wafers, a database for storing data from the optical lithographer, and a cluster E-beam lithography system for exposing fine patterns on the wafers, wherein the cluster E-beam lithography system includes a plurality of E-beam devices and a control center for managing wafers to be lithographically processed by the plurality of E-beam devices, each E-beam device having a compound objective lens for inspecting wafers and drawing fine patterns on the wafers in situ.

The present invention also provides a lithography process, which comprises steps of performing optical lithography process to wafers with a rough pattern thereon in an optical lithography system; transferring the wafers from the optical lithography system to a control center of a cluster EBL system; distributing the wafers into E-beam devices of the cluster EBL system; receiving data processed by the optical lithography system; inspecting the rough pattern on the wafers by using the E-beam devices; computing key lithography data for E-beams device; managing an E-beam lithography process dataflow; and performing the E-beam lithography process to the wafers.

The compound objective lens comprises two excitation coils and two magnetic lenses with a shared pole piece. One of the two magnetic lenses inspects the wafers and the other one of the two magnetic lenses draws the fine patterns to the wafers. The shared pole piece is electrically isolated from the compound objective lens. The compound objective lens comprises electrostatic lens.

The present invention provides a hybrid lithography system, which comprises an optical lithographer for exposing rough patterns on wafers, a database for storing data from the optical lithographer, and an E-beam lithography device for exposing fine patterns on the wafers, wherein the E-beam lithography device has a multi-axis magnetic lens for controlling a plurality of electron beams on the wafers.

The multi-axis magnetic lens comprises a common excitation coil for generating magnetic field. The multi-axis magnetic lens comprises an upper pole piece and a lower pole piece with a plurality of through holes in the upper pole piece and the lower pole piece, a plurality of magnetic rings inside the plurality of through holes and a plurality of non-magnetic insert rings between the magnetic rings and the upper pole piece as well as the lower pole piece.

An object of the present invention is to provide a hybrid lithography system that combines one optical lithographer to expose larger pattern area and a cluster E-beam lithography system to expose pattern area where request higher resolution.

Another object of the present invention is to provide a hybrid lithography system that an inspection step can be performed prior to E-beam lithography step.

Merely by way of example, the present invention has been used onto smallest feature lithograph such as gate, AA and contact, but it would be recognized that the present invention has a much broader range of applicability.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

FIG. 1 is a simplified diagrammatic representation of a cluster E-beam lithography system according to an embodiment of the present invention.

FIG. 2 is a simplified diagrammatic representation of a functional flowchart of lithography process by using the cluster EBL system according to an embodiment of the present invention.

FIG. 3 is a schematic illustration of a multi-axis magnetic lens used in an E-beam device in accordance with an embodiment of the present invention

FIG. 4 is a schematic illustration of a compound objective lens used in an E-beam device in accordance with an embodiment of the present invention

FIG. 5 is a simplified diagrammatic representation of a functional flowchart of lithography process within an inspection step using the cluster EBL system according to an embodiment of the present invention.

### DETAILED DESCRIPTION OF EXAMPLE EMBODIMENTS

Various example embodiments of the present invention will now be described more fully with reference to the accompanying drawings in which some example embodiments of the invention are shown. In the drawings, relative size may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

In the embodiment of the invention, AA (active area) includes a MOS (metal-oxide-semiconductor) device formed in and on a semiconductor wafer. Lithography, sometimes denoted as litho, is a process transferring patterns from a mask/reticle to a semiconductor wafer. In a system and method in accordance with the present invention, lithography may refer to optical lithography or E-beam lithography. E-beam (EB), meaning electron beam, can be used as an inspection probe or can be used to write a fine pattern to a photoresist layer on a semiconductor wafer. An E-beam device is a device using an E-beam to inspect wafer or write fine pattern on a wafer. An EB nano-litho chamber includes an E-beam device in a chamber. A fine pattern means that a feature of the pattern is less than 32 nm node, while a rough pattern means that a feature of the pattern is larger than 32 nm node.

The present invention relates to an advanced lithography system to gain high throughput and high resolution in semiconductor lithography practice. More specifically, embodiments of the present invention provide a hybrid system that combines optical and E-beam lithography system to achieve the object. Merely by way of example, a method and system in accordance with the present invention has been used on a smallest feature lithograph (such as gate, AA (active area) and contact), but it would be recognized by one of ordinary skill in the art that the system and method in accordance with the present invention has a much broader range of applicability.

As explained above, the E-beam lithographer is characterized by high resolution and low throughput; the optical lithographer has a high throughput but not a high enough resolution for sub 32 nm nodes in a semiconductor device. Moreover, a hybrid system with a cluster E-beam lithography system and an optical lithography system can take advantage of both. More specifically, the cluster E-beam lithography system can be used for exposure for small features and the optical lithography system can be used for exposure for larger patterns.

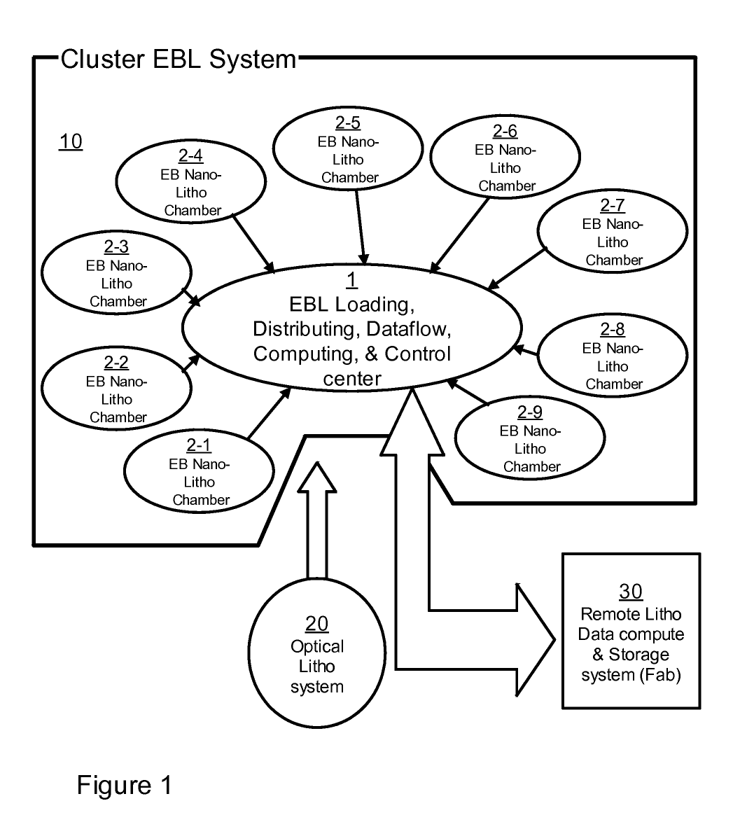

FIG. 1 is a simplified diagrammatic representation of a hybrid lithography system concept to achieve high throughput and high resolution lithograph for sub 32 nm patterns. The optical lithography system 20 exposes the larger feature of the pattern on a wafer. Then, the wafer is passed to the cluster EBL (E-beam lithography) system 10 to expose the sub 32 nm features on the wafer. The cluster E-beam lithography system 10 is configured more than one E-beam nano-lithographer chambers 2-1 to 2-9 to match the throughput depth; a control center 1 that managing wafer loading/unloading, wafer distributing, dataflow, data processing and system control; a litho data compute and storage system 30 that compute and storage key litho parameters. The litho data compute and storage system 30 may be located at a remote site per customer request.

The EB nano-litho chambers 2-1 to 2-9 are places to process lithography step by using electrons as the exposure source. The electrons have a much shorter wavelength compared to the EUV (extreme ultraviolet) wavelength, and the wavelength of electrons can be varied and controlled by the acceleration energy of the EB system. Wafers with patterns thereon need these EB nano-litho chambers 2-1 to 2-9 for further lithography process for finer or smaller pattern less than 32 nm.

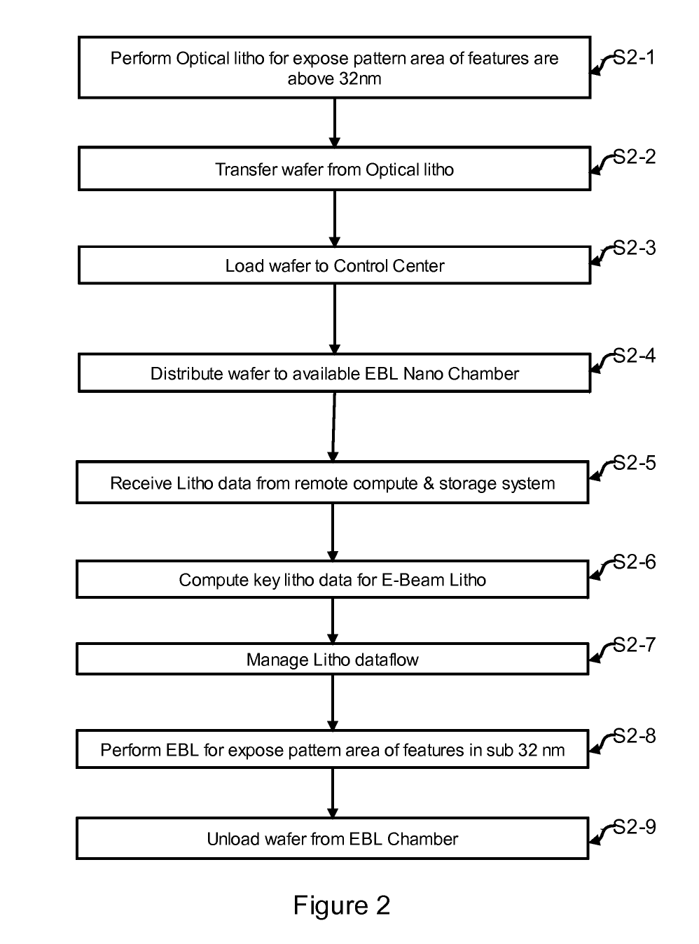

The FIG. 2 illustrates a detailed functional flowchart of the cluster EBL system 10. First, a wafer is exposed to an optical lithography system 20 for pattern area with feature more than 32 nm, or larger feature (step S2-1). Then, the wafer is transferred from the Optical lithography system 20 (step S2-2). The wafer is then transferred into control center 1 for the next lithography process (step S2-3). Next, the wafer is distributed to the EB nano-litho chambers 2-1 to 2-9 (step S2-4). Because the optical lithography system has more throughput than the EB lithography system, there should be many wafers processed by the optical lithography system 20 and the wafers should wait for the control center 1 to be distributed into the EB nano-litho chambers 2-1 to 2-9. Next, data for these wafers in the EB nano-litho chambers 2-1 to 2-9 are received from the remote litho data compute and storage system 30 (step S2-5), and then key litho data for EB nano-litho chambers 2-1 to 2-9 are computed by the control center 1 (step S2-6). The control center 30 then manages lithography dataflow for wafers in the EB nano-litho chambers 2-1 to 2-9 (step S2-7). A second lithography process is performed to the wafers in the EB nano-litho chambers 2-1 to 2-9 by using electrons as an exposure source for pattern area of features less than 32 nm or smaller patterns (step S2-8). The wafers then are unloaded from the cluster EBL system 10 (step S2-9).

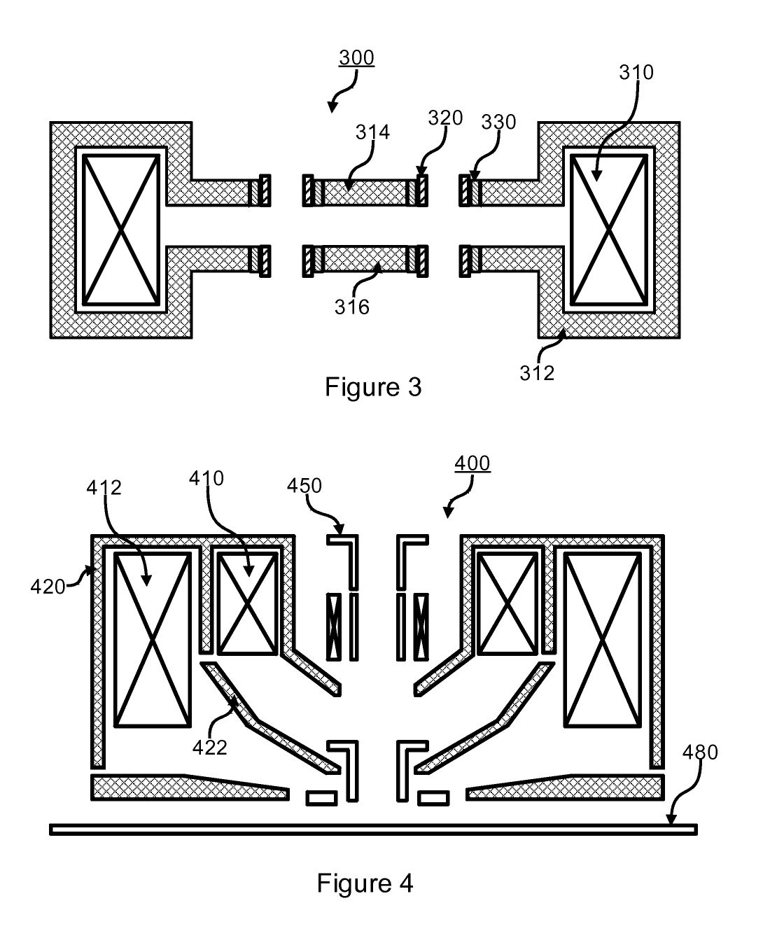

However, conventional EB lithography system uses only one column; that means only one electron source is provided for one EB lithography system. One electron source for the entire wafer in a lithography process is a time consuming job and one may spend about several hours processing one wafer. A multi-column EB lithography system therefore should be developed for a commercial concern. FIG. 3 illustrates a cross-sectional view of an objective lens 300 with two holes for two primary beams of electrons in an EB lithography system. The objective lens 300 has an excitation coil 310 with a magnetic yoke 312 enclosing the excitation coil 310. The yoke 312 has an upper pole piece 314 and a lower pole piece 316. Each hole has two magnetic rings 320 respectively within the upper pole piece 314 and the lower pole piece 316 with non-magnetic insert rings 330 between the magnetic rings 320 and the yoke 312. Detailed structure of the objective lens is shown in U.S. patent application Ser. No. 12/636,007, filed Dec. 17, 2009, the entire disclosure of which is incorporated herein by reference. In theory, such a two-hole design can reduce lithography process duration by half. If a multi-column is utilized, such as three or more columns, the duration of lithography process can be significantly reduced in turn reducing process cycle time. Further, the footprint of the cluster EBL system can also be reduced to a reasonable range for a foundry.

Another advantage for E-beam lithography system is that an inspection step after optical lithography process can be performed immediately before the EB lithography process. However, the landing energy for inspection on a wafer with photoresist layer thereon and the EB lithography process is different. The E-beam system for inspection requires a small current with low landing energy while the E-beam system for the lithography process requires a large current with high landing energy. A general objective lens can not meet both requirements. However, a compound objective lens for meeting both requirements is shown in FIG. 4. A compound objective lens 400, that focuses the primary beam on a wafer 480, is provided with two excitation coils 410 and 412 with a magnetic yoke 420 enclosing the two excitation coils 410 and 412. A common shared pole piece 422 is electrically isolated from the yoke 420. This compound objective lens 400 also includes some other electrostatic electrodes 450 for controlling primary beam potential and condensing the primary beam. Such a compound objective lens 400 is disclosed in U.S. patent application Ser. No. 11/923,012, filed Oct. 24, 2007, the entire disclosure of which is incorporated herein by reference. The compound objective lens can control both low and high landing energy in one E-beam system. Thus, wafers that have been processed by optical lithography process can be inspected first to check if there is any defect can be repaired or should be reworked. If a critical defect should be reworked and found at this inspection step, it can save time to the following etching process. If there is no defect that should be reworked, or defects that should be repaired by the EB lithography system, wafers are then processed to the EB lithography process.

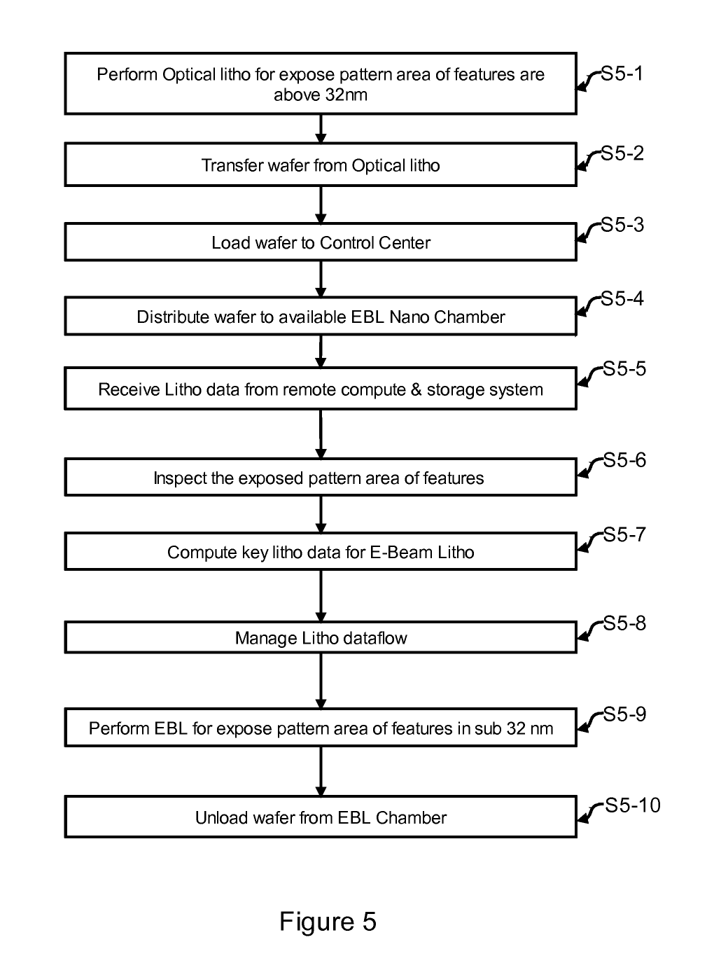

FIG. 5 illustrates the detailed functional flowchart of the cluster EBL system 10 with a further inspection step. First, a wafer is exposed to an optical lithography system 20 for pattern area with a feature more than 32 nm, or larger feature (step S5-1). Then, the wafer is transferred from the Optical lithography system 20 (step S5-2). The wafer is then transferred into the control center 1 for the next lithography process (step S5-3). Next, the wafer is distributed to the EB nano-litho chambers 2-1 to 2-9 (step S5-4). Because the optical lithography system has more throughput than the EB lithography system, there should be many wafers processed by the optical lithography system 20 and the wafers should wait for the control center 1 to be distributed into the EB nano-litho chambers 2-1 to 2-9. Next, data for these wafers in the EB nano-litho chambers 2-1 to 2-9 are received from the remote litho data compute and storage system 30 (step S5-5), and then an inspection step is performed on the exposed pattern area of the feature on the wafers (step S5-6). In this step, the exposed patterns will be developed first and then inspected to check if any defect exists. Then, key litho data for the EB nano-litho chambers 2-1 to 2-9 are computed by the control center 1 (step S5-7). The control center 30 then manages lithography dataflow for wafers in the EB nano-litho chambers 2-1 to 2-9 (step S5-8). A second lithography process is performed to the wafers in the EB nano-litho chambers 2-1 to 2-9 by using electrons as an exposure source for the pattern area of features less than 32 nm or smaller patterns (step S5-9). The wafers then are unloaded from the cluster EBL system 10 (step S5-10).

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A hybrid lithography system comprising:
an optical lithographer for exposing rough patterns on wafers;
a database for storing data from the optical lithographer; and
a cluster E-beam lithography system for exposing fine patterns on the wafers, wherein the cluster E-beam lithography system includes a plurality of E-beam devices and a control center for managing wafers to be lithographically processed by the plurality of E-beam devices, each E-beam device having a compound objective lens for inspecting wafers and drawing fine patterns on the wafers in situ.

2. The hybrid lithography system of claim 1, wherein the compound objective lens comprises two excitation coils and two magnetic lenses with a shared pole piece.

3. The hybrid lithography system of claim 2, wherein one of the two magnetic lenses inspects the wafers and the other one of the two magnetic lenses draws the fine patterns to the wafers.

4. The hybrid lithography system of claim 2, wherein the shared pole piece is electrically isolated from the compound objective lens.

5. The hybrid lithography system of claim 2, wherein the compound objective lens comprises an electrostatic lens.

6. A hybrid lithography system comprising:
an optical lithographer for exposing rough patterns on wafers;
a database for storing data from the optical lithographer; and
an E-beam lithography device for exposing fine patterns on the wafers, wherein the E-beam lithography device has a multi-axis magnetic lens for controlling a plurality of electron beams on the wafers.

7. The hybrid lithography system according to claim 6, wherein the multi-axis magnetic lens comprises a common excitation coil for generating magnetic field.

8. The hybrid lithography system according to claim 7, wherein the multi-axis magnetic lens comprises an upper pole piece and a lower pole piece with a plurality of through holes in the upper pole piece and the lower pole piece, a plurality of magnetic rings inside the plurality of through holes and a plurality of non-magnetic insert rings between the magnetic rings and the upper pole piece as well as the lower pole piece.

9. A lithography process, comprising:
performing optical lithography process to wafers with a rough pattern thereon in an optical lithography system;
transferring the wafers from the optical lithography system to a control center of a cluster EBL system;
distributing the wafers into E-beam devices of the cluster EBL system;
receiving data processed by the optical lithography system;
inspecting the rough pattern on the wafers by using the E-beam devices;
computing key lithography data for E-beams device;
managing an E-beam lithography process dataflow; and
performing the E-beam lithography process to the wafers.

10. The lithography process according to claim 9, wherein each of the E-beam devices has a compound objective lens.

11. The lithography process according to claim 10, wherein the compound objective lens comprises two excitation coils and two magnetic lenses with a shared pole piece.

12. The lithography process according to claim 11, wherein one of the two magnetic lenses inspects the wafers and the other one of the two magnetic lenses draws the fine patterns to the wafers.

13. The lithography process according to claim 11, wherein the shared pole piece is electrically isolated from the compound objective lens.

14. The lithography process according to claim 11, wherein the compound objective lens comprises an electrostatic lens.
